(19) United States
(12) Patent Application Publication
(10) Pub. No.: US 2008/0068224 A1
(43) Pub. Date: Mar. 20, 2008

(54) Actuation Apparatus

(75) Inventor: Peter Holland, London (GB)

Correspondence Address: LAUBSCHER & LAUBSCHER, P.C., 1160 SPA ROAD, SUITE 2B, ANNAPOLIS, MD, 21403, US

(73) Assignee: SENSITIVITY LIMITED, London (GB)

(21) Appl. No.: 11/570,646

(22) PCT Filed: Jun. 10, 2005
(86) PCT No.: PCT/GB05/02311

§ 371 Date: Sep. 10, 2007

(30) Foreign Application Priority Data
Jun. 28, 2004 (GB) 0414437.4
Mar. 2, 2005 (GB) 0504329.4

(51) Int. Cl. H03K 17/94

(52) U.S. Cl. 341/20

(57) ABSTRACT

An apparatus for actuating one or more functions on a remote electronic device comprises one or more button members (41) provided within a housing having no electronic components, each button member (41) being associated with at least one fluid channel (45a, 45b). A remote conversion means is also provided which is associated with the or each fluid channel (450, 45b). The or each button member (41) is movable with respect to its at least one fluid channel (450, 45b) to cause an internal pressure change in the fluid channel (450, 45b). The remote conversion means can detect any pressure change in the fluid channels to thereby produce an electrical signal for actuating an appropriate function on the remote electronic device.

The present invention relates to apparatus for actuating one or more functions on an electronic device.

In this regard, electrical devices such as computers are becoming increasingly part of our everyday function. More and more we are using computers both at work and home. Virtually wherever we are, we are in close proximity to a computer. This increased exposure to electronic devices, whilst of course adding enormous benefits to our overall lifestyle, also poses new risks and hazards.

In this regard, there are environments where such radiation is undesirable and to be avoided. For example, certain electronic devices will not themselves function correctly if subjected to unwanted radiation. Moreover, in wet or moist environments, any form of unprotected electronic circuitry has the potential of failing and/or causing electric shock.

Moreover, the levels of radiation emitted from even standard electronic equipment can significantly affect the well being of susceptible individuals.

The present invention seeks to provide in one aspect an arrangement which can help to alleviate such problems.

According to a first aspect of the present invention there is provided apparatus for actuating one or more functions on a remote electronic device; the apparatus comprising: one or more button members provided within a housing having no electronic components, each button member being associated with at least one fluid channel; a remote conversion means associated with the or each fluid channel; wherein the or each button member is movable with respect to its at least one said fluid channel to cause an internal pressure change in said at least one fluid channel, said remote conversion means detecting the pressure change to thereby produce an electrical signal for actuating an appropriate function on said remote electronic device.

In this way, an apparatus is provided which locally is free from any form of electric/electronic circuitry and can remotely operate an electronic device, such as a computer. In this way the apparatus assists to alleviate the health problems associated with coming into close contact with radiation from electrical circuitry in apparatus such as computer keyboards, mice and pointing devices.

Preferably, movement of, the or each button member causes compression of the at least one fluid channel to thereby increase the internal pressure therein. In such an embodiment, it is not necessary that a pump is provided to sustain a positive or negative pressure within the fluid channels. Therefore, the manufacturing and running costs of the apparatus can be reduced.

Preferably, the at least one fluid channel is provided with one or more bulbous sections associated with each button member, wherein movement of said button member causes compression of the associated bulbous section.

Preferably, each bulbous section is in the form of a bellow.

In alternative embodiments, movement of the or each button member can cause one or more apertures in the fluid channel associated with said button member to open for allowing the fluid channel to be connected to an ambient pressure, resulting in a pressure change in the fluid channel; and wherein said button member is ordinarily biassed to close said aperture. In this way, the present invention advantageously uses the natural atmospheric pressure to actuate a function on the remote device.

Preferably, the apparatus further comprises means for creating a pressure gradient between said fluid in said fluid channel and ambient pressure.

Preferably, the or each button has associated therewith a shutter element for operably opening and closing said aperture, wherein upon actuation of said button member, said shutter element opens said fluid channel to ambient pressure.

Preferably, said remote conversion means comprises sensor means for detecting a pressure change.

Preferably, the conversion means further comprises sensor adjustment means for adjusting the sensitivity of the sensor. Therefore, advantageously, the sensitivity of the sensor can be adjusted according to the ambient atmospheric pressure and the pressure drop required within the fluid channels to optimise the detection of a change in pressure.

Preferably, the greater the internal pressure change in said at least one fluid channel, the greater the electrical signal produced by the conversion means. This allows the signals produced by the conversion means to have variable intensities which can then impart variable effects upon the function that the electrical signal will produce. For example, if the electrical signal is to impart movement of a cursor across a computer screen, the greater the electrical signal produced, the faster or further the cursor may move.

Preferably, said one or more button members are interconnected within a matrix of fluid paths; a plurality of fluid channels are provided for conveying fluid media between said matrix and said remote conversion means; the or each button member having a unique address within the matrix such that when operable by a user, a unique signature for that button member is detectable from said plurality of fluid channels; whereby said conversion means can detect said or each unique signature on operation of said or each button member and produce an electrical signal for actuating an appropriate function on a remote electronic device. In this way, a pressure increase in a combination of fluid channels can be used to determine which of the button members is pressed.

According to a second aspect of the present invention, there is provided apparatus for actuating one or more functions on a remote electronic device; the apparatus comprising: one or more button members interconnected within a matrix of fluid paths; a plurality of fluid channels for conveying fluid media between said matrix and a remote conversion means; the or each button member having a unique address within the matrix such that when operable by a user, a unique signature for that button member is detectable from said plurality of fluid channels; whereby said conversion means can detect said or each unique signature on operation of said or each button member and produce an electrical signal for actuating an appropriate function on a remote electronic device.

Therefore, the present invention allows the button members to effectively share pneumatic paths. Accordingly, the size of the cabling, piping or tubing required can be minimised, resulting in reduced costs, size and weight.

Preferably, the fluid channels are pneumatic channels.

Preferably, the fluid channels are hydraulic channels.

Preferably, the button member comprises one or more actuating members for acting on the at least one fluid channel to cause an internal pressure change therein.

According to a third aspect of the present invention, there is provided apparatus for actuating at least one function on a remote electronic device, the apparatus comprising: one or more button members provided within a housing having no electronic components, each button member being associated with at least one fluid channel; a remote conversion means associated with the or each said fluid channel; wherein the or each said button member is movable with respect to its at least one said fluid channel to cause compression of the same, whereby operation of said button member causes an internal pressure change in said at least one fluid channel, said conversion means detecting the pressure change to thereby produce an electrical signal for actuating an appropriate function on said remote electronic device.

Preferably, the resting internal pressure of said at least one fluid channel is provided at atmospheric pressure or at greater than atmospheric pressure.

Preferably, said at least one fluid channel is resiliently deformable. In this way, the elasticity of the fluid channel itself can be used to re-inflate the channel after compression.

Preferably, the at least one fluid channel is formed of rubber or plastic.

Preferably, said at least one fluid channel are formed by coupling a flexible layer, having a pattern for said least one fluid channel formed therein, to a rigid substrate.

According to a fourth aspect of the present invention, there is provided apparatus for actuating one or more functions on a remote electronic device; the apparatus comprising: one or more button members provided within a housing having no electronic components, each button member being associated with at least one aperture of a pneumatic channel; a remote conversion means associated with said pneumatic channel; and means for creating a reduced pressure within said pneumatic channel; wherein said button member is ordinarily biassed to close said aperture, whereby actuation of said button member opens said aperture for allowing said channel to be connected to ambient pressure, said conversion means detecting a resulting pressure change to thereby produce an electrical signal for actuating an appropriate function on said remote electronic device.

Preferably, said one or more each button members are connectable to a plurality of pneumatic channels through one or more apertures; whereby actuation of a said button member opens said one or more apertures for allowing said plurality of pneumatic channels to be connected to ambient pressure, said conversion means detecting a resulting pressure change in said plurality of pneumatic channels, thereby producing an electrical signal for actuating an appropriate function on said remote electronic device.

According to a fifth aspect of the present invention, there is provided a computer mouse comprising any apparatus described above.

According to a sixth aspect of the present invention, there is provided a keyboard or keypad comprising apparatus according to any apparatus described above.

According to a seventh aspect of the present invention, there is provided a method of manufacturing apparatus for actuating one or more functions on a remote electronic device; the method comprising the steps of: providing a plurality of lamina-like layers, each layer having one or more pneumatic paths or path sections disposed therein; combining the plurality of layers to form a manifold housing a three dimensional matrix of such pneumatic paths; associating one or more button members with said matrix, the or each button member having a unique address within the matrix; and coupling a plurality of pneumatic channels for conveying pneumatic media between said matrix and a remote conversion means, said conversion means detecting a unique signature for each button member on operation thereof and producing an electrical signal for actuating an appropriate function on a remote electronic device.

Therefore, the present invention provides a method allowing simple manufacture of a three dimensional matrix of pneumatic paths which allows the buttons to effectively share pneumatic paths achieving the associated advantages described above.

Examples of the present invention will now be described with reference to the accompanying drawings, in which:

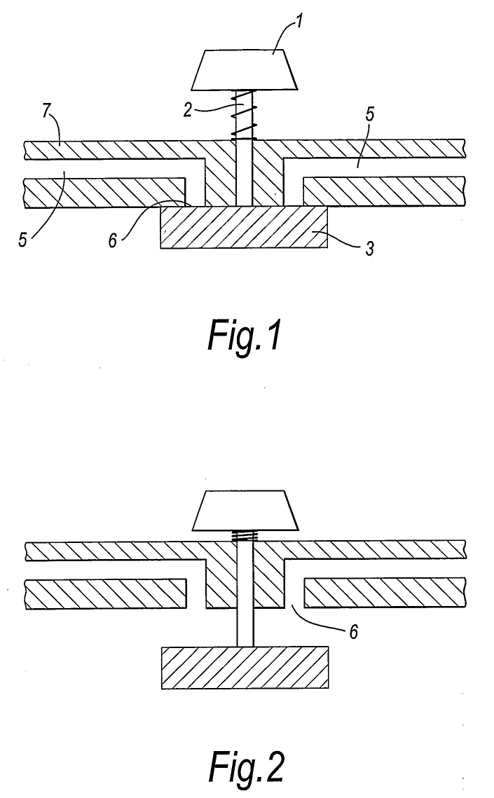

FIG. 1 shows a cut away view of apparatus a first embodiment of the present invention with a button member in an upper unpressed position;

FIG. 2 shows a cut away view of apparatus of a first embodiment of the present invention with a button member in a lower pressed position;

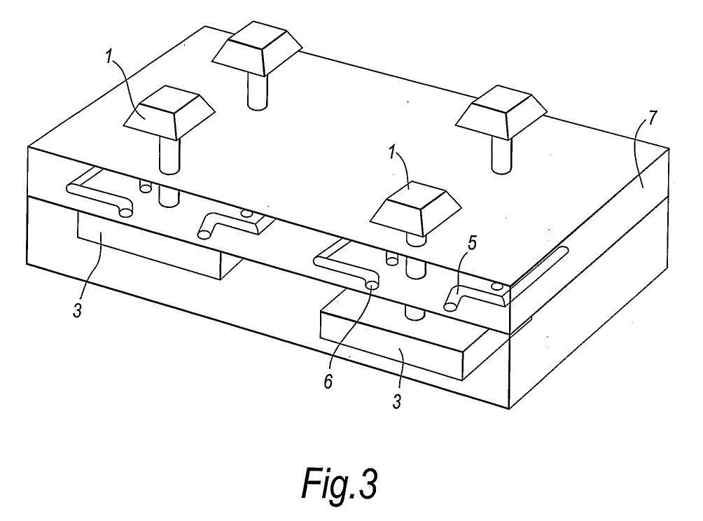

FIG. 3 shows a part cross-sectional view of apparatus of a first embodiment of the present invention; and

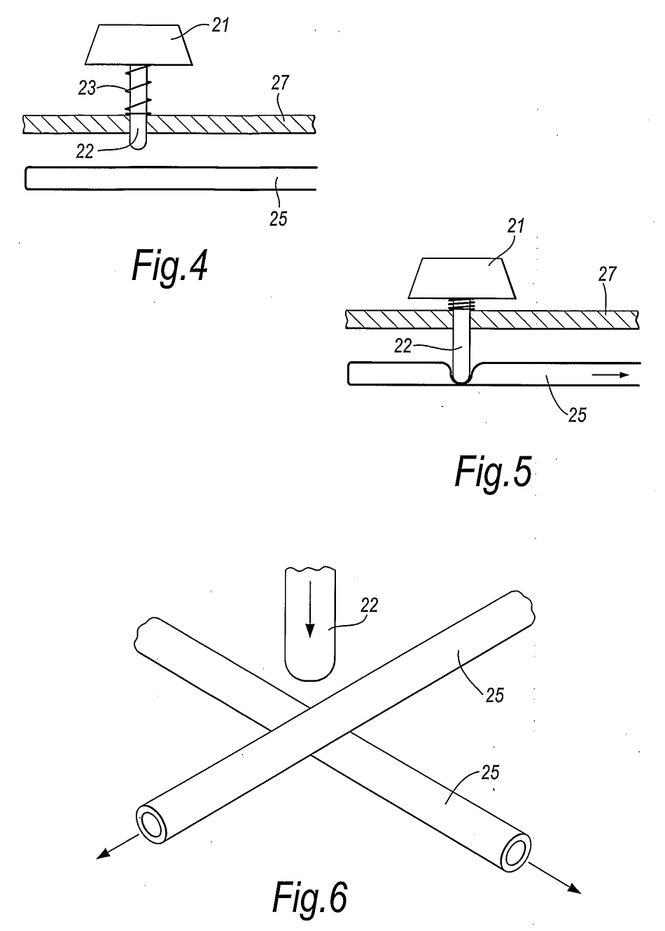

FIG. 4 shows a cut away view of apparatus of a second embodiment of the present invention in a first un-operated position;

FIG. 5 shows a cut away view of apparatus of a second embodiment of the present invention in an operated position;

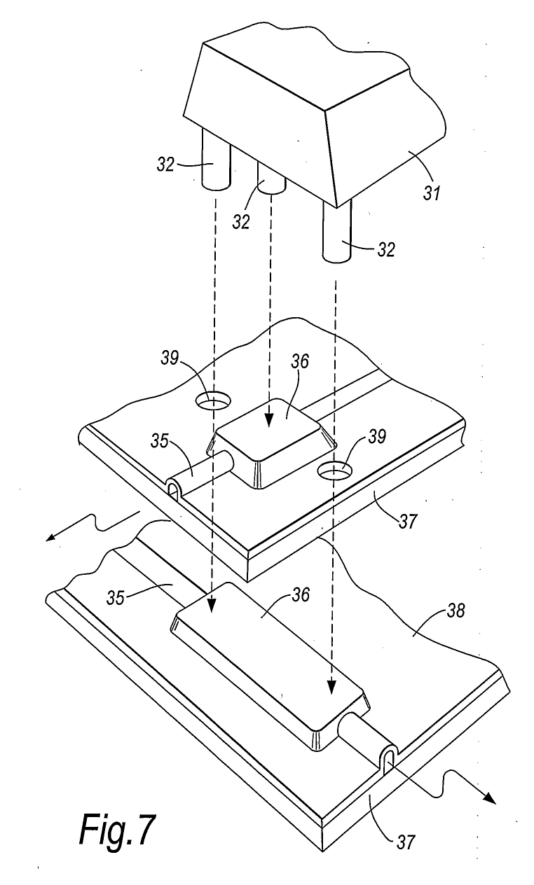

FIG. 6 shows a view of fluid channels and an actuator in the apparatus of a second embodiment of the present invention;

FIG. 7 shows an expanded perspective view of apparatus of a third embodiment of the present invention;

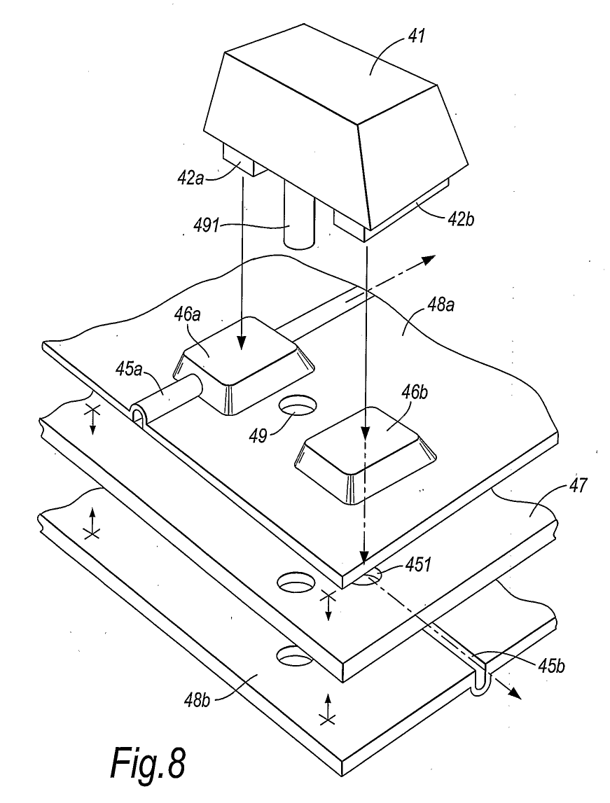

FIG. 8 shows an expanded perspective view of apparatus of a fourth embodiment of the present invention;

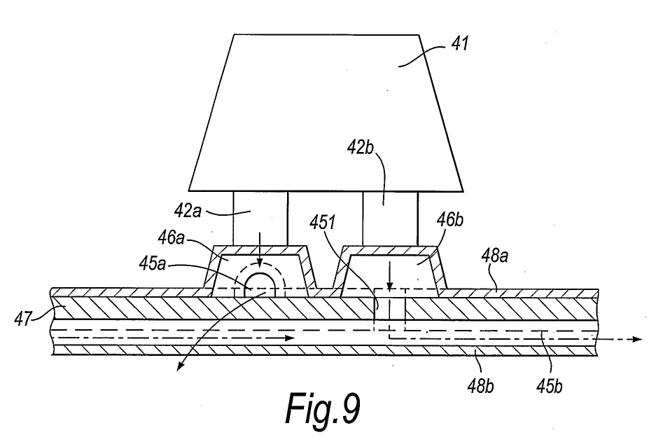

FIG. 9 shows a cross-sectional view of the apparatus of the fourth embodiment of the present invention;

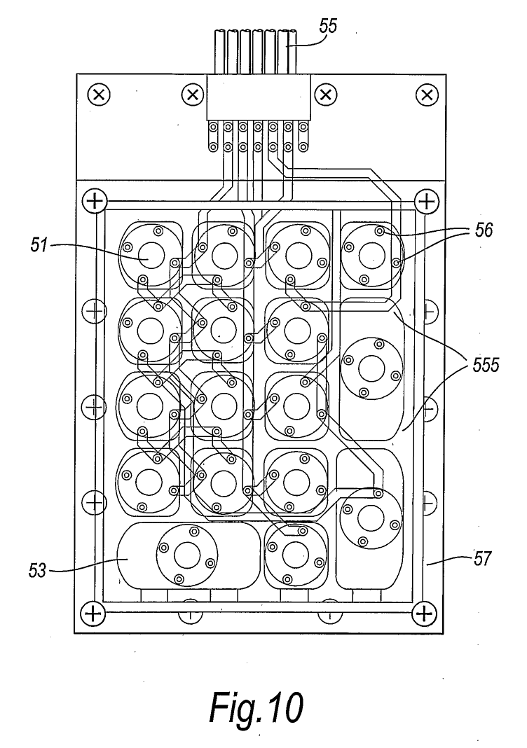

FIG. 10 shows a top view of apparatus of a fifth embodiment of the present invention;

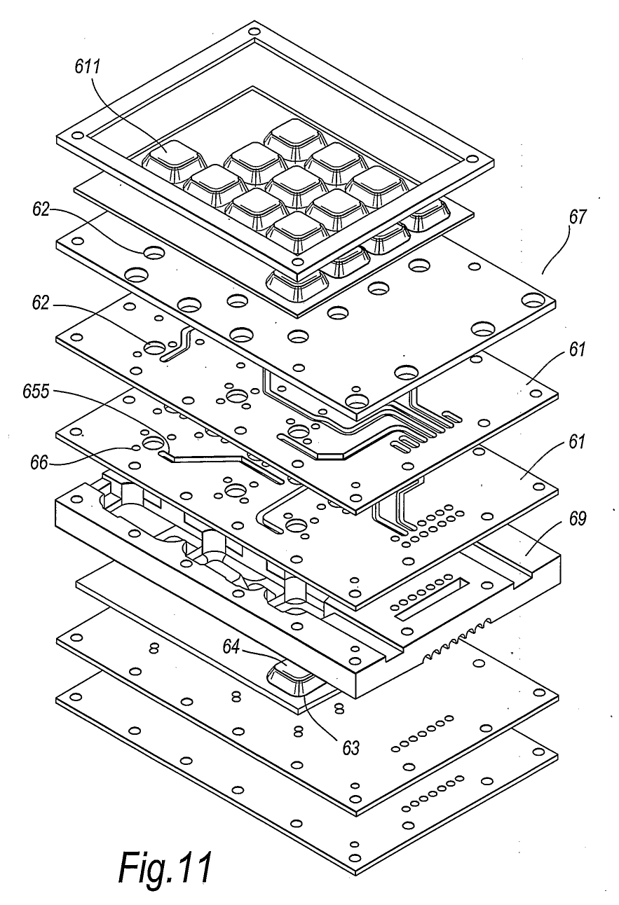

FIG. 11 shows an exploded view of apparatus of a sixth embodiment of the present invention;

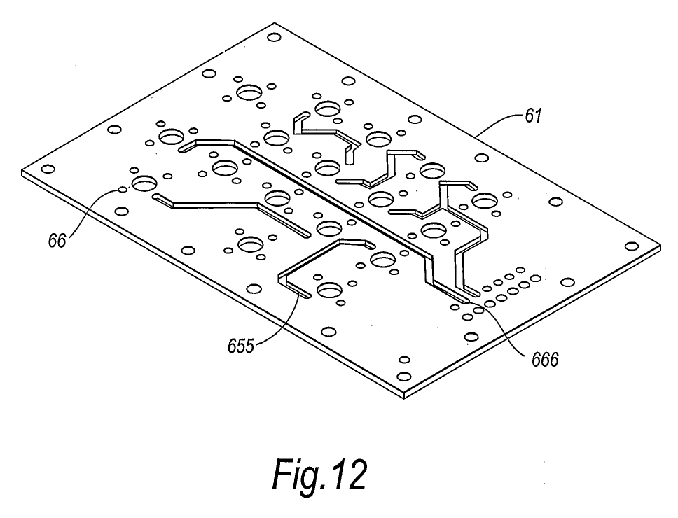

FIG. 12 shows in detail a pneumatic layer from FIG. 11;

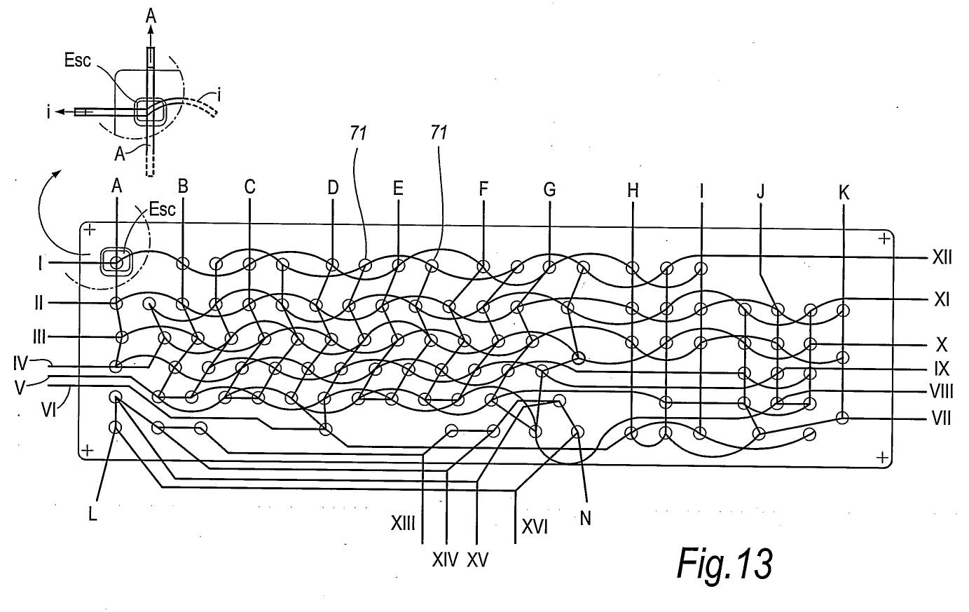

FIG. 13 shows apparatus of a seventh embodiment of the present invention;

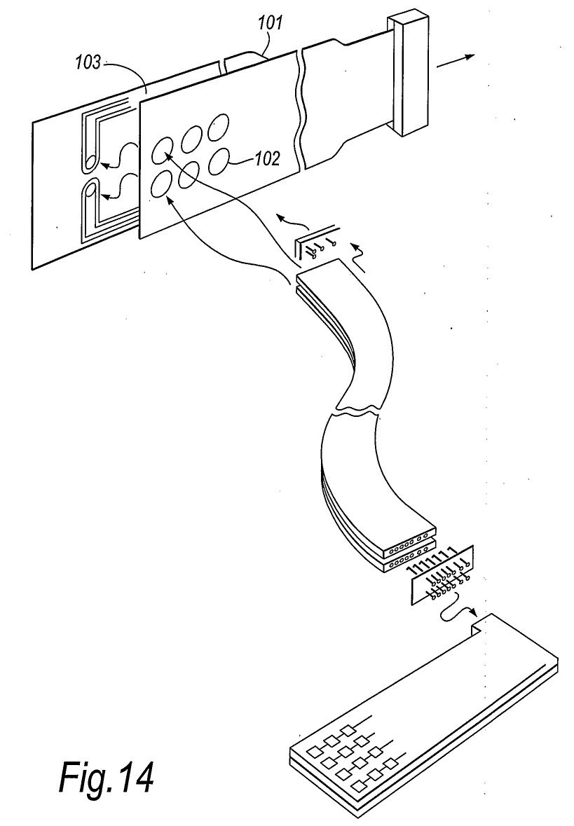

FIG. 14 shows in cross section the keyboard arrangement shown in FIG. 13 connecting to a remote sensing apparatus;

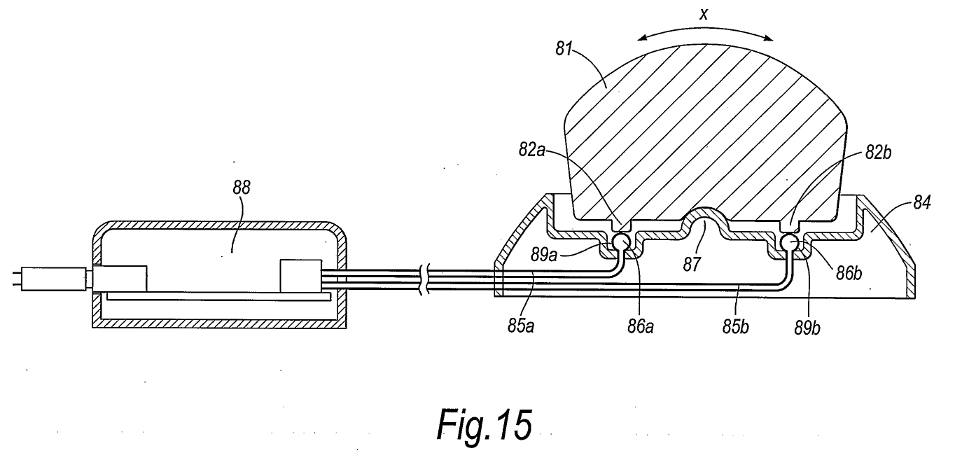

FIG. 15 shows a part cross-sectional view of apparatus of an eighth embodiment of the present invention;

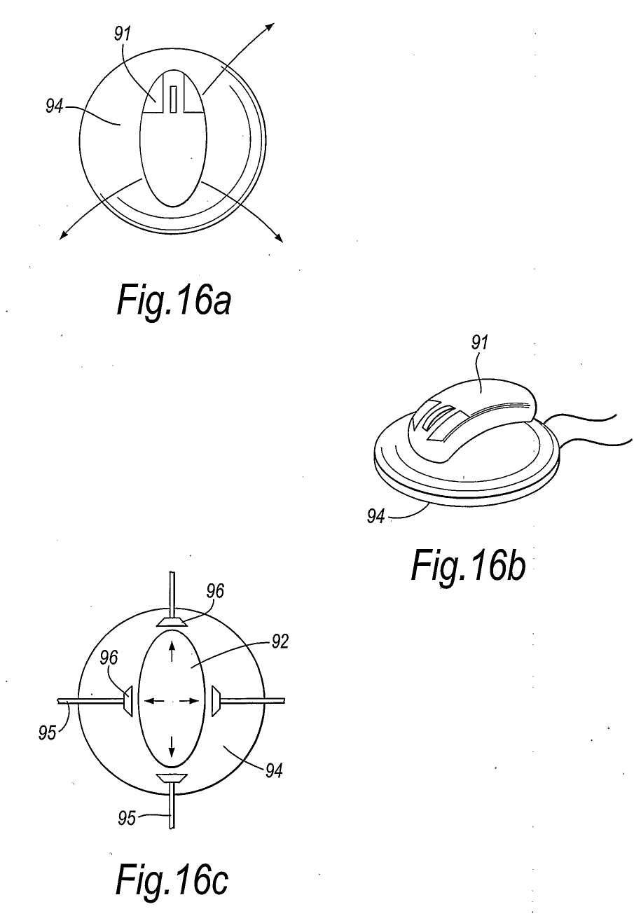

FIGS. 16a to 16c show apparatus of a ninth embodiment of the present invention, where FIG. 16a shows a plan view, FIG. 16b shows a perspective view, and FIG. 16c shows a cross-sectional plan view.

FIGS. 1 and 2 show, in simplified form, apparatus according to a first embodiment of the present invention, and more particularly an input button, free from any form of electric circuitry.

The button is part of a larger array of buttons, such as an array of keys on a keyboard. The button comprises a button member 1, and a shutter 3 connected to the button member 1.

The button member 1 and the shutter 3 are moveably secured by a housing 7, whereby a user, upon pushing the button member 1, will cause the button member 1 and the shutter 3 to move downward from a rest position to a lower position, as shown in FIG. 2.

The input button includes a biassing element, such as a spring, surrounding the actuation member 2, to resiliently urge the button member 1 and the shutter 3 back to the upper rest position.

The button member 1 may, alternatively, not be directly connected to the shutter 3, but rather the shutter 3 may form a separate component onto which the button member 1 abuts. For example, the shutter 3 may be formed on a rubber key mat positioned beneath the button member 1. In an unpressed state, the spring action of the rubber key mat urges the shutter 3, and hence the button member 1, into an upper rest position. When a user presses the button member 1, it acts as a plunger on the shutter 3 and forces it down into a lower position.

In the example shown in FIG. 1, a plurality of such button members 1 are provided within an array, which is provided with one or more media paths, disposed above the shutter 3. In this example the media paths are pneumatic channels 5.

The proximate ends of the pneumatic channels 5 open at apertures 6 onto the underside of the housing 7. When the shutter 3 is in its upper position, it is seated against the underside of the housing 7 so as to act as a seal and blocks apertures 6.

Preferably, the shutter is formed of an elastic material such as foam rubber so as to form an effective seal and is biassed into the upper position by a spring surrounding the actuation member 2, or another resilient configuration such as a rubber key mat.

At a remote end of the pneumatic channels 5, a pump is provided which acts to reduce the air pressure within the channel, thereby generating a partial vacuum within the pneumatic channels. When the button is in a normal unpressed state, this partial vacuum is maintained by the pump and air is prevented from entering the pneumatic channels 5 by the shutter 3. Preferably, the pressure within the pneumatic channels in the unpressed state is approximately 5 PSI below atmospheric pressure. Additionally, the remote end of the each channel is also provided with a pressure sensor for detecting a change in pressure within the channel and responsively outputting an electrical signal.

Upon a user pressing a button, the shutter 3 is moved towards its lower position, thereby opening the apertures 6 and allowing air to flow through the pneumatic channels 5.

Subsequently, there is an increase of pressure within the pneumatic channels as the vacuum is breached. This increase in pressure is then detected by the pressure sensors connected to the remote ends of each channel, which in turn outputs an electrical signal.

In a preferred embodiment the pressure sensor has a sensor adjustment means which allows the sensitivity of the sensor to be adjusted. In this way, the sensitivity of the sensor can be adjusted according to the level of ambient atmospheric pressure and the required reduced pressure level within the pneumatic channels, to thereby optimise the detection of a change in pressure. For example, at altitude, where atmospheric pressure is lower, a user or an automated system may increase the sensitivity of the sensor to account for the reduced pressure gradient between atmosphere and the partial vacuum.

FIG. 3 shows a four button section of an array of buttons similar to that described above with reference to FIGS. 1 and 2. Within the housing 7 there are a number of pneumatic channels 5 which open at apertures 6 onto the underside of the housing 7. Three of the button members are unpressed, whilst the button 1 at the bottom right side of the diagram is in its lower position as if its button member 1 has been pressed by a user. In this case therefore, the four apertures 6 associated with that depressed button are simultaneously opened as the shutter 3 moves downward. Accordingly, the vacuums within each of the associated four pneumatic channels 5 are breached and there is an influx of air from the atmosphere. The pressure sensors located at the remote ends of these pneumatic channels detect the increased pressure and output an electrical signal, which can then be processed by a micro controller to determine which of the buttons has been pressed.

Advantageously, with this embodiment, since the pneumatic channels are normally under a partial vacuum, any bending and compression of the channels, is less liable to result in false positive detection of a button member actuation, compared to pressurised systems.

FIGS. 4 and 5 show, in simplified form, an input button according to a second embodiment of the present invention. As with the first embodiment, the button is in practice part of a larger array of buttons, such as an array of keys on a keyboard.

Similar to the first embodiment, a user pushing the button member 21 will cause the button member 21 and the actuating member 22 to move downward from a rest position, as shown in FIG. 1, to a lower position, as shown in FIG. 2. Again, a biassing element 23, such as a spring, is provided to resiliently urge the button member 21 and the actuating member 22 back to the upper rest position.

Beneath each button member 21, disposed below the actuating member 22, one or more media paths are provided. For simplicity only one media path is shown in FIGS. 4 and 5. In this example, the media paths are fluid (hydraulic or pneumatic) channels 25. The channels 25 may be formed of any suitable material, for example, rubber or plastic tubing, cabling or piping. This allows the channels 25 to be resiliently deformable for allowing multiple compressions thereof, and flexible for being positioned within articles of various sizes or shapes.

As shown, the actuating member 22 is configured to compress the channel 5 when the button member 21 is urged into a lower position. In their normal state, the channels 25 can either be maintained at a positive pressure, i.e. above atmospheric pressure, or allowed to remain at atmospheric pressure. If the channels 25 are to be maintained at a positive pressure, then a pump (not shown) is provided which acts to increase the pressure within the channel 25. If the channels are allowed to remain at atmospheric pressure, then a pump is not required.

When the button member 21 is in a normal unpressed state, the pressure in the channel 25 remains constant. The remote end of the each channel is provided with a pressure sensor for detecting a change in pressure within the channel and responsively outputting an electrical signal.

Upon a user pressing a button member, the actuating member 22 is moved towards its lower position, thereby compressing the channel 25. Subsequently, there is an increase of pressure within the channel as the volume within the pneumatic channel is effectively reduced. This increase in pressure is then detected by the pressure sensors connected to the remote ends of each channel, which in turn outputs an electrical signal indicating that the pressure has increased.

The channels may be filled with any suitable fluid medium, for example, air or liquid.

The pressure sensor is able to detect the intensity of the compression imparted by the actuating member, i.e. the greater the force of compression, the greater the signal produced.

In order to ensure a change in pressure upon compression of the channel and to enable positive pressurisation of the channel prior to compression by an actuating member, the end of the channel which is not connected to a pressure sensor is preferably sealed. In this connection, as detailed below with reference to further embodiments of the present invention, one end of the channel may be formed into a sealed bulbous element for interaction with the actuating member 22.

FIG. 6 shows perspective representation of two channels 25 disposed below the actuating member 22 according to the second embodiment discussed above with reference to FIGS. 4 and 5. As will be evident, movement of the actuating member 22 into its lower position will cause both of the two channels 25 to be compressed, resulting in an in an increase of pressure within both channels 25, which can then be detected at the remote ends of each channel. The arrangement of channels 25 shown in FIG. 6 is particularly useful within the context of an array of buttons, such as an array of keys on a keyboard, since the plurality of buttons can be positioned along a grid-like matrix of channels, with each button associated with a unique combination of channels. Such an arrangement is discussed in more detail later.

FIG. 7 shows, in an expanded perspective view, an input button according to a third embodiment of the present invention, which can be used as part of a larger array of buttons. As with the second embodiment, a user pushing the button member 31 will cause the actuating member 32 to move downwardly to compress media pathways, in the form of channels 35, beneath. In this embodiment however, the channels 35 are provided with enlarged or bulbous bellow sections 36. These bellow sections 36 are compressed by the actuation member 32 when it is moved into a lower position. Since the bellow sections 36 contain a large volume of fluid (e.g. air or a liquid) relative the narrower channel sections of the channel 35, their compression results in a large increase in pressure which can more easily be detected by pressure sensors at the distal end of channels 35.

In the construction shown in FIG. 7, the two associated channels 35 are formed on separate layers which can then be superimposed on top of one another. Each layer comprises a rigid substrate 37 and a flexible layer 38, preferably formed of flexible silicon rubber or another elastic material, which can be bonded thereto, for example as a self adhesive layer. The flexible layers 38 are formed with the pattern for the channels 35 and the bellow sections 36. Accordingly, once the flexible layers 38 are bonded with their respective substrates 37, the channels 35 and the bellow sections 36 are formed by the gaps between the pattern and the substrate 37. In this way, a simple substrate can be used, which can then have a complex arrangement of channels 35 and bellow sections fitted onto it. Indeed, multiple channels, and their bellow sections, can be formed on a single layer. Typically these multiple channels will be formed in parallel lines for use as a x- or y-axis in a grid-like matrix of a button array.

Once assembled, the layers are arranged on top of one another. A button member 31, preferably formed of a plastics material, can be aligned above the bellows. An actuation member 32, in the form of three plungers, is provided on the button member 31. The central plunger is configured to compress the bellow 36 on the upper layer, when the actuation member is in its lower position. The two peripheral plungers are configured to extend through apertures 39 provided in the upper layer to the lower layer, where they can compress the bellow 36 on the lower layer, when the actuation member is in its lower position.

FIG. 8 shows, in an expanded perspective view, an input button according to a fourth embodiment of the present invention, which can be used as part of a larger array of buttons. This embodiment is in many ways similar to the third embodiment described above with reference to FIG. 7. In this case however, a single rigid substrate 47 is used; with an upper flexible layer 48a bonded to a top surface of the substrate 47, and a lower flexible layer 48b bonded to a bottom surface of the substrate 47.

The upper flexible layer 48a contains a channel 45a with associated bellow sections 46a which operate in the same way as discussed above. Also provided on the upper flexible layer 48a is a bellow section 46b which is associated with a channel 45b formed on the lower flexible layer 48b through aperture 451. A button member 41 is aligned with the layers, and hence the bellows 46a and 46b, by an alignment peg 491 which fits into apertures 49. Once aligned, the actuation member 42 has two protrusions which are positioned above the bellows, and the button being pressed causes them to move downwardly to compress the bellow sections.

FIG. 9 shows a simplified cross-sectional view of the fourth embodiment. When the button member is depressed, the protrusions of the actuation member move downwardly to compress bellow sections 46a and 46b simultaneously. In this way, fluid (e.g. air or a liquid) in the bellow section's cavity is forced outward. In the case of bellow section 46a, the fluid is forced along channel 45a formed on the upper flexible layer 48a. In the case of bellow section 46b, the fluid is forced down through aperture 451 in the substrate 47 and along channel 45b formed on the lower flexible layer 48b. Pressure sensors can then be provided at the distal ends of these channels for detecting the depression of the button member 41.

In the above embodiments it is preferable that the channels have internal bore sizes in the region of 1 mm. If the bore sizes are too small, fluid flow is too restricted and the response speed is slower. If the bores are too large, the volume of fluid is increased and the strength of the signal is reduced. There are of course also a number of additional features which can be included in the above designs. For example, in embodiments which rely on increases in pressure, such as the second, third and fourth embodiments described above, a totally sealed system can cause false activation of the pressure sensors if, for example, direct sunlight heats up the fluid inside the channels. Accordingly, it is preferable that a small vent hole is provided in the channels which allows for slow changes in pressure to be equalised. The vent hole should be pin-hole size to avoid pressure being bled off too quickly from a key press.

The arrangement of the above described embodiments within the context of a larger array of buttons will now be described.

FIG. 10 shows a fifth embodiment of the present invention where a plurality of buttons like those shown in FIGS. 1 to 3 are arranged within a specific array or grid. As shown, the example array of FIG. 10 encompasses 17 buttons like those described above with reference to FIGS. 1 to 3 forming a pneumatic keypad, although clearly more, i.e. 110, would be provided for a conventional “QWERTY” keyboard. The pneumatic channels comprise seven main pneumatic channels 55 connected to a matrix of pneumatic paths 555. In this regard, the shutter 53 of each button is arranged to alter a flow the of media, in this case air, in the one or more pneumatic paths 555 relating to that button when the associated button is depressed, so that depression of each button will cause a unique signature in the main pneumatic channels 55.

The main pneumatic channels 55 are connected to remote sensing apparatus and micro controller, which can convert and process the unique signature into an electronic signal for use in operating one or more functions of electronic device. In this embodiment, a pump is used to create a partial vacuum within the main pneumatic channels 55. Preferably, air flow restricting means are incorporated into the connections between the main pneumatic channels 55 and the pump. The airflow restricting means help prevent pressure increases in activated channels interfering with inactive channels. Conveniently, the main pneumatic channels 55 can be arranged to form essentially a single cable of multi-core tubing. In this way, the majority of the length of the main pneumatic channels 55 between the matrix and the pump appears as a single cable or tube, with each of the main pneumatic channels 55 being a separate core within the multi-core tube.

Accordingly, the cabling or tubing is kept compact and tidy.

Each button has up to four apertures 56 associated with it which are connected to a unique combination of pneumatic paths 555 and hence main pneumatic channels 55. More or less apertures 56 can be used with different button configurations and/or different button members. When a button is pressed, a pressure increase intone or more of the pneumatic paths is simultaneously detected by the pressure sensors at the remote ends of the main pneumatic channels 55. The combination of the pneumatic paths 555, and hence the main pneumatic channels 55, in which a pressure increase is detected, is then used by the micro controller to identify which of the buttons has been pressed, and in response output the appropriate electrical signal to an electronic device.

FIG. 11 shows an exploded cross section view of apparatus of a sixth embodiment of the present invention having an array of buttons and a housing 67 similar to that described above with reference to FIG. 10. The housing 57 is a composite of a number of laminate layers which are shown separated. During the manufacturing process these layers are sandwiched together. Two of the laminate layers are pneumatic layers 61, each of which having a number of button apertures 62. When the pneumatic layers 611 are combined together, corresponding button apertures 62 from each pneumatic layer align with one another to form a hole through which the button member 611 can be fitted. As shown, the two pneumatic layers 61 have a configuration of pneumatic paths or path sections 655 travelling through them. When these pneumatic layers 61 are combined, a three dimensional network or matrix of pneumatic paths is formed.

Each of the buttons has up to four apertures 66 which open onto the underside of the bottom pneumatic layer. The apertures 66 project up from the under surface and connect into one or more of the pneumatic paths 655 in one or more of the layers 61. For example, an aperture may connect into a pneumatic path in the bottom layer or project up to connect to a pneumatic path in the top layer. The pneumatic layers' 61 three dimensional structure allows the pneumatic paths 655 to be isolated from one another to form a dense network of paths. A vestibular layer 69 is provided beneath the bottom pneumatic layer and forms a cavity into which the apertures 66 open to the outside atmosphere. In this embodiment, a key mat 63, having a number of shutters 64 formed thereon, is provided below the vestibular layer 69. When fitted together, the shutters 64 fit inside the cavity formed by the vestibular layer 69 and align with the corresponding button apertures 62 in the pneumatic layers 61 above. In this way, when a button member 61 is fitted, it passes through the button apertures 62 and abuts at or adjacent one of the shutters 64.

In a normal un-pressed state, the shutters 64 sit in a upper rest position and seal the apertures 66. When a button member is operated by a user, the button member pushes one of the shutters 64 downwardly, opening the apertures 66 for that button to the cavity in the vestibular layer 69, thereby allowing atmospheric pressure to enter the pneumatic paths 655. As each button is connected to a unique combination of pneumatic paths 655, operation of a particular button therefore results in a unique signature created by paths 655 in the main pneumatic channels which service them. This allows the number of main pneumatic channels required to service the array of buttons to be reduced.

FIG. 12 shows one of pneumatic layers 61 as described above in reference to FIG. 11. As shown, each button 611 has up to four apertures 66 associated with it. The pneumatic layer 61 also has a number of pneumatic paths 655 formed therein which are connected to one or more of the apertures 66. Two of the pneumatic paths 655 are connected to two connection ports 666. The remaining pneumatic paths 655 are configured to connect to other pneumatic paths in adjacent pneumatic layers. Either directly or via adjacent pneumatic layers each of the pneumatic paths 655 is connected to at least one connection port 666, the connection ports connecting the matrix of pneumatic paths to the main pneumatic channels (not shown) servicing them. By forming the pneumatic matrix from a plurality of pneumatic layers, a complex three dimensional network or manifold can be formed using simplified manufacturing techniques. For example, each layer could be produced by mass manufacturing methods such as die casting or injection moulding, thereby allowing relatively cheap manufacture. Alternatively, a sheet material could be produced for each pneumatic layer and the paths and holes could machined or etched into them to form the pneumatic paths. Lamination of the pneumatic layers may be achieved, for example, by mechanical means, heating to cause bonding between layers, or by use of adhesives.

FIG. 13 shows apparatus of a seventh embodiment of the present invention where an alternative array arrangement of buttons is used, in this case using buttons like those shown in any of FIGS. 4 to 9. As shown, the array of buttons are arranged in a grid-like matrix which forms a keyboard arrangement.

Several channels, A-M, i-xvi, are arranged in a matrix so that each button member 71 is positioned above one or more, and typically two, channels. For clarity, each channel is depicted as a single line. In this respect, the actuating member 72 of each button member 71 is arranged to compress the one or more channels relating to that button member when the associated button member is depressed, so that depression of each button member will cause a unique signature of pressure change in the channels detected by pressure sensors connected to the end of each channel.

Accordingly, in the example shown in FIG. 13, if the button member labelled “Esc” is depressed, the pressure within the channels labelled “A” and “i” will increase causing the sensors connected to these to generate an electrical signal. In this arrangement, only signals generated simultaneously by the sensors connected to channels “A” and “i” will be indicative of the button member labelled “Esc”. This is more clearly shown in the enlarged portion of FIG. 13.

The configuration of the matrix, as shown above in reference to FIGS. 10 and 13 allows the button members to effectively share channels. For example, in the embodiment shown in FIG. 13, by using a matrix of channels, only 29 channels are required to service 105 separate buttons. By sharing channels in this way, and hence reducing the number of channels required, the size of the cabling, piping or tubing required for a keypad, for example, can be minimised so as to be suitable for a desktop keypad or keyboard. Moreover, by reducing the number of channels, the number of seals and connections that are required is reduced. There are also significant cost savings as less piping is used and a reduced number of pressure detectors is required.

In the above examples, the distal ends of the channels are connected to remote sensing apparatus and micro controller, which can convert and process the unique signature into an electronic signal for use in operating one or more functions of an electronic device. Conveniently, the channels can be arranged to form essentially a single cable of multi-core tubing. In this way, the majority of the length of the main channels between the matrix and the sensors appears as a single cable or tube, with each of the channels being a separate core within the multi-core tube. Accordingly, the cabling or tubing is kept compact and tidy.

FIG. 14 shows the keyboard arrangement shown in FIG. 13 connecting to a remote sensing apparatus 101. In the embodiment shown in FIG. 14, the sensing apparatus 101 comprises a flexible polyester sheet embossed with low pressure domes 102 which are printed with conductive inks.

When a button member is pressed, a pressure increase in one or more of the channels is transferred to the distal ends of the channels where it is applied to the conductive domes 102. This causes the conductive domes to connect a circuit 103 on an underlying substrate. This connection indicates that there has been a pressure increase in that channel. The combination of the channels in which a pressure increase is detected is then used by the micro controller to identify which of the button members has been pressed, and in response output the appropriate electrical signal to an electronic device. As will be appreciated, a similar detector could be used to detect an increase in pressure in the case of the buttons shown in FIGS. 1 to 3. Other detectors could alternatively be used, provided they can detect a change in pressure in the channels, for example silicon pressure sensors, piezo-electric sensors, capacitive sensors, mechanical sensors could all be used.

FIG. 15 shows a cross sectional view of an eighth embodiment of the present invention, whereby the apparatus is adapted for use in a computer mouse. In this example, the button member 81 is in the form of a rocker body with two actuating members 82a, 82b positioned either side of a pivot means 87. The rocker body 81 is moveable within housing 84. Positioned below each actuating member 82a, 82b is a bulbous portion 86a, 86b of channels 85a, 85b with the distal ends of the channels being connected to a pressure sensor 88. Each bulbous portion 86a, 86b is disposed within a respective recess 89a, 89b formed in the housing 84 below each actuating member 82a, 82b. The pivot means 87 allows the rocker body 81 to rock in the direction shown by the arrow x and so alternately causing the actuating members 82a, 82b to compress the bulbous portions 86a, 86b of the channels 85a, 85b. In the present example the pivot means is provided in the housing 84, however, it will be appreciated that the pivot means may also be provided on the underside of the mouse body 81.

As the bulbous portions 86a, 86b are alternatively compressed, the pressure inside the pneumatic channels 85a, 85b is likewise alternatively increased. The increase in pressure is detected by the pressure sensor 88 and then converted to an electrical signal for remote output to a computer (not shown). Each bulbous portion 86a, 86b, and hence each channel can be configured to produce an electrical output corresponding to a direction of movement. For example, in the embodiment shown in FIG. 15, compression of bulbous portion 86a may produce an electrical signal to effect a first direction of movement of a cursor on a computer screen, whilst compression of bulbous portion 86b may produce an electrical signal to effect a second direction of movement of a curser on a computer screen. Whilst only two bulbous portions are shown in the embodiment of FIG. 15, further bulbous portions may be provided in order to effect movement of a cursor in a range of directions. For example, with four bulbous portions, four directions of movement can be imparted. Furthermore, for each bulbous portion there may exist a corresponding actuating member positioned above said bulbous portion. Alternatively, a range of bulbous portions may be provided in a ring configuration under a pivotable ring shaped actuating member.

Further button members may be provided within the mouse for effecting selection of icons highlighted by a cursor on a computer screen. These further button members may be provided in accordance with one of the second to fourth embodiments of the present invention, i.e. with an actuating member for compressing a channel when urged into a lower position, or for compressing a bulbous portion of a channel.

In the embodiment described with reference to FIG. 15 above, it will be appreciated that the bulbous portions are a preferred feature, with the possibility that the actuating members 82 may simply act upon the channels 85a, 85b directly.

FIGS. 16a to 16c show apparatus of a ninth embodiment of the present invention, similar to that shown in FIG. 15, whereby the apparatus is adapted for use in a computer mouse.

FIGS. 16a and 16b respectively show a plan view and a perspective view of the mouse. In this example, the button member is in the form of a mouse shaped slider 91 which sits on housing 94. The mouse shaped slider 91 is moveable relative to the housing 94 for effecting the various directional movements of the mouse.

FIG. 16c shows a cross-sectional plan view of the mouse. As shown, in this example, four bellows 96 are provided inside the housing 94. An actuation member 92 is provided on the underside of the mouse shaped slider 91 so that when the mouse shaped slider 91 is moved in a particular direction, one or more of the bellows 96 is compressed by the actuation member 92, resulting in an increase in pressure in the associated channels 95. As with previous embodiments, this increase in pressure can then be used, via pressure sensor and microprocessor to effect movement of a cursor in a range of directions.

As shown, the mouse also includes a number of buttons on the mouse shaped slider 91 allowing for the selection of icons highlighted by a cursor on a computer screen. These further buttons involve an actuating member for compressing a channel when urged into a lower position.

It will be appreciated that a number of variations can be made to the apparatus. For example, whilst, the above description relates primarily to buttons for keyboard like structures, the invention encompasses other forms of input devices, such as a computer mouse. Furthermore, the fluid used in the channels may be any suitable liquid, such as water or an oil. Alternatively it may be a gas such as air. A reservoir may be provided for topping up the channels, preferably with a non-return valve.

1. Apparatus for actuating one or more functions on a remote electronic device; the apparatus comprising:
a housing having no electronic components and comprising at least one substantially rigid substrate;
one or more fluid path layers coupled to the or each substantially rigid substrate layer, said one or more fluid path layers having a pattern for a matrix of fluid paths formed therein such that said matrix is formed between said substantially rigid substrate layer and the one or more fluid path layers;
a plurality of fluid channels for conveying fluid media between the matrix and a remote conversion means;
a plurality of button members each button member being associated with at least one fluid path to have a unique address within the matrix of fluid paths, and each button member being movable relative to its respective at least one fluid path to cause an internal pressure change therein, said internal pressure change being detectable in the plurality of fluid channels as a unique signature for that button member;
whereby said remote conversion means can detect said unique signature on operation of each button member and produce an electrical signal for actuating an appropriate function on a remote electronic device.

2. Apparatus according to claim 1, wherein movement of the or each button member causes compression of the fluid path layer at the at least one fluid channel to thereby increase the internal pressure therein.

3. Apparatus according to claim 1, wherein the at least one fluid path is provided with one or more bulbous sections associated with each button member, wherein movement of said button member causes compression of the associated bulbous section.

4. Apparatus according to claim 3, wherein each bulbous section is in the form of a bellow.

5. Apparatus according to claim 1, wherein said remote conversion means comprises sensor means for detecting a pressure change.

6. Apparatus according to claim 5, wherein the conversion means further comprises sensor adjustment means for adjusting the sensitivity of the sensor.

7. Apparatus according to claim 1, wherein the conversion means is responsive to different pressure changes such that the greater the internal pressure change in said plurality of fluid paths and fluid channels, the greater the electrical signal produced by the conversion means.

8. An apparatus according to claim 1, wherein the fluid paths and fluid channels are pneumatic channels.

9. An apparatus according to claim 1, wherein the fluid paths and fluid channels are hydraulic channels.

10. Apparatus according to claim 1, wherein each button member comprises one or more actuating members for acting on the associated at least one fluid path to cause an internal pressure change therein.

11. Apparatus according claim 1, wherein the resting internal pressure of said matrix of fluid paths is provided at atmospheric pressure or at greater than atmospheric pressure.

12. Apparatus according to claim 1, wherein said fluid paths are resiliently deformable.

13. An apparatus according to claim 1, wherein the at least one fluid path layers forming said fluid paths are formed of flexible material.

14. An apparatus according claim 1, wherein the one or more fluid path layers is bonded to the or each substantially rigid substrate layer.

15. A computer mouse comprising apparatus according to claim 1.

16. A keyboard or keypad comprising apparatus according to claim 1.

17. A method of manufacturing apparatus for actuating one or more functions on a remote electronic device; the method comprising the steps of:
forming one or more fluid path layers having a pattern for a matrix of fluid paths formed therein;
coupling said one or more fluid path layers to at least one substantially rigid substrate to form said matrix there between, said at least one rigid substrate provided in a housing having no electronic components;
associating a plurality of button members with said matrix of fluid paths, each button member being associated with at least one fluid path to have a unique address within the matrix, and each button member being movable relative to its respective at least one fluid path to cause an internal pressure change therein;
providing a plurality of fluid channels for conveying fluid media between the matrix and a remote conversion means,
wherein an internal pressure change in the fluid paths is detectable in the plurality of fluid channels as a unique signature for each button member and is detectable by said remote conversion for actuating an appropriate function on a remote electronic device.

18-25. (canceled)
